(19) United States
(12) Patent Application Publication
(10) Pub. No.: US 2018/0364477 A1
(43) Pub. Date: Dec. 20, 2018

(54) LIGHT-EMITTING DEVICE

(71) Applicant: SHIMADZU CORPORATION, Kyoto-Shi (JP)

(72) Inventors: Naoki WAKABAYASHI, Kyoto-Shi (JP); Nobuyuki IWAI, Kyoto-Shi (JP)

(73) Assignee: SHIMADZU CORPORATION, Kyoto-Shi (JP)

(21) Appl. No.: 16/005,213

(22) Filed: Jun. 11, 2018

(30) Foreign Application Priority Data
Jun. 16, 2017 (JP) 2017-118265

(51) Int. Cl. G02B 27/00; G02B 27/30; G02B 27/10; G02B 27/12; H01S 5/00

(52) U.S. Cl. CPC G02B 27/0025; G02B 27/30; H01S 5/0071; G02B 27/123; G02B 27/1006

(57) ABSTRACT

A light-emitting device suppresses chromatic aberration following reduction of the beam-interval relative to a plurality of beams to be combined. The device has a plurality of light sources 10 and a beam-interval reducing device 30, having a first optical element 31 to which a plurality of beams L is incident, a second optical element 32 to which a plurality of beams L emitted from the first optical element 31, specifies the beam-interval of the plurality of beams L emitted from the second optical element 32 to be narrower than the beam-interval of the plurality of beams L incident to the first optical element 31, emits a plurality of beams L and cancels respectively each the chromatic aberration that occurs when the first optical element 31 and the second optical element 32 pass through.

### CROSS REFERENCE TO RELATED APPLICATIONS

This application relates to, and claims priority from, JP 2017-118265 filed Jun. 16, 2017, the entire contents of which are incorporated herein by reference.

### FIGURE SELECTED FOR PUBLICATION

FIG. 1

### BACKGROUND OF THE INVENTION

### Field of the Invention

The present invention relates to a light-emitting device that combines the lights emitted from a plurality of light sources.

### Description of the Related Art

A light-emitting device that combines beams emitted from a plurality of light sources is used for a high-power output and so forth. When combing a plurality of beams, an anamorphic optical element such as a prism is used as a means to reduce the beam-interval. For example, a plurality of beams emitted from the light source is combined using a converging lens following narrowing the reciprocal interval with the anamorphic optical element (e.g., refer to Patent Document 1).

### RELATED PRIOR ART DOCUMENTS

### Patent Document

Patent Document 1: JP Patent Published 2005-114977 A

### ASPECTS AND SUMMARY OF THE INVENTION

### Objects to be Solved

When a semiconductor laser and so forth is the light source, the central wavelength of the beam emitted from the light source varies due to the temperature of the light source and fluctuation of the driving electric current that drives the light source. It is problematic that a traveling direction of the beam and a diameter of the beam, which passes through the anamorphic optical element, vary due to the chromatic aberration that takes place along with the variation of the central wavelength.

Considering the above problem, a purpose of the present invention is to provide a light-emitting device that suppresses the chromatic aberration following reduction of the beam-interval relative to a plurality of beams to be combined.

### Means for Solving the Problem

According to the aspect of the present invention, a light-emitting device comprises a plurality of light sources and a beam-interval reducing device that further comprises a first optical element to which a plurality of beams emitted from each of the light sources is incident and a second optical element to which a plurality of beams that are emitted from the first optical element are incident; wherein the beam-interval reducing device that emits a plurality of beams while reducing a beam-interval of the plurality of beams emitted from the second optical element to be narrower than a beam-interval of the plurality of beams that are incident to the first optical element, and the light-emitting device has an optical characteristic by which the first optical element and the second optical element cancel each chromatic aberration taking place therefrom when the beams transmit therethrough.

### Effect of the Invention

According to the present invention, a light-emitting device that suppresses the chromatic aberration following reduction of the beam-interval relative to a plurality of beams to be combined.

The above and other aspects, features and advantages of the present invention will become apparent from the following description read in conjunction with the accompanying drawings, in which like reference numerals designate the same elements.

### BRIEF DESCRIPTION OF THE DRAWINGS

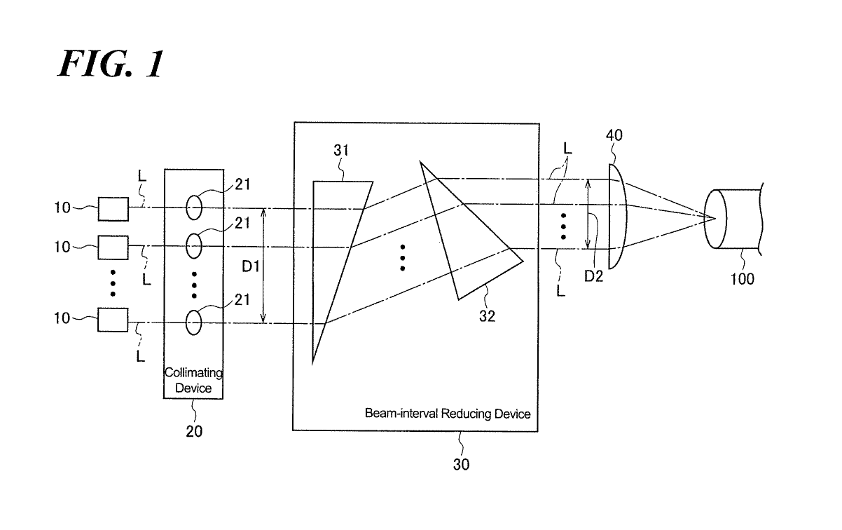

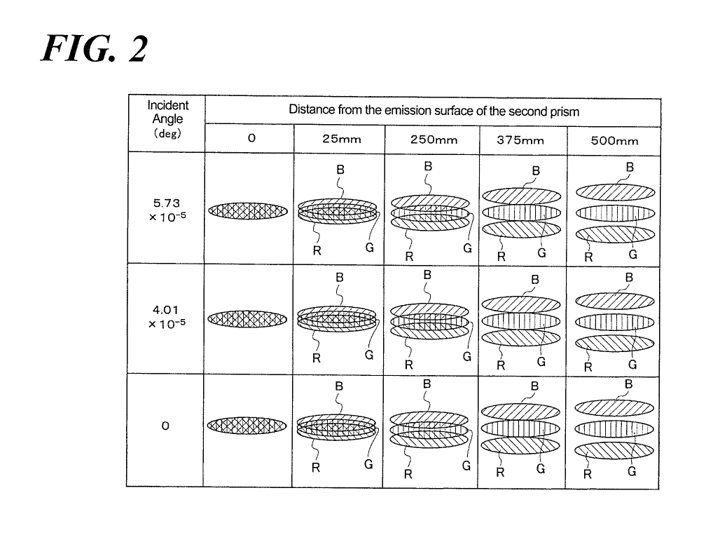

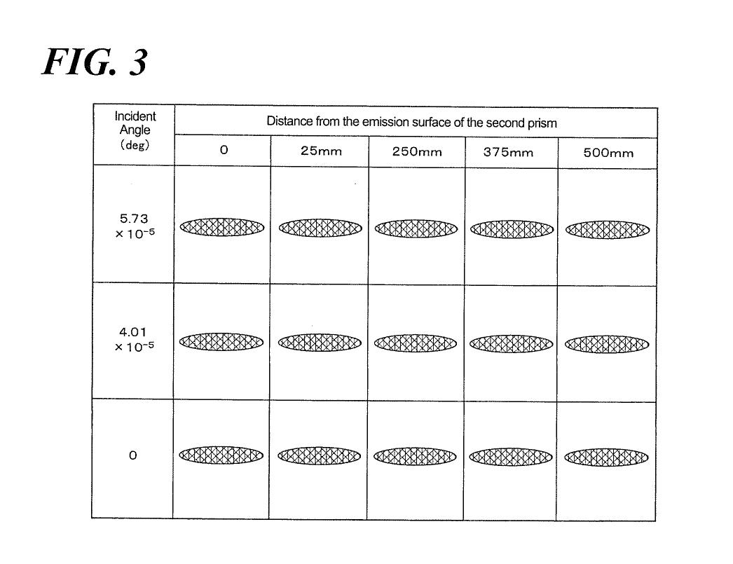

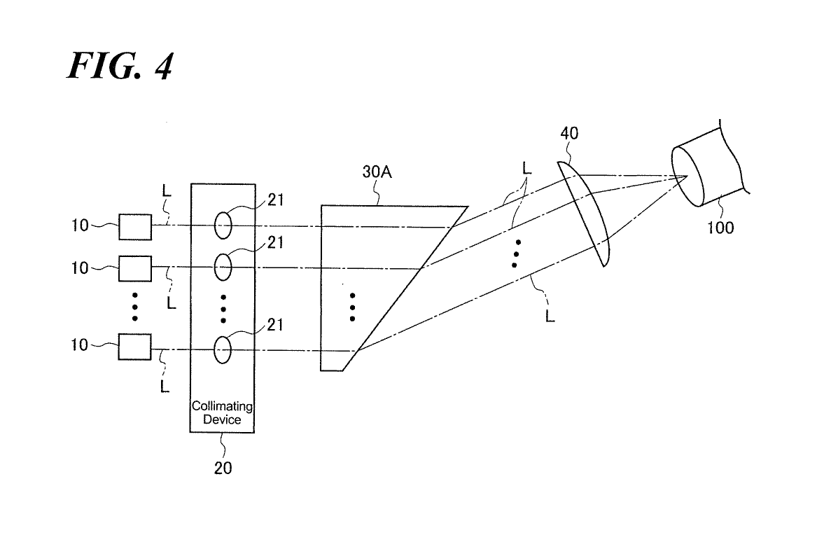

FIG. 1 is a schematic diagram illustrating the structure of a light-emitting device according to the aspect of the Embodiment of the present invention.

FIG. 2 is illustrating the calculation results of chromatic aberration based on the light-emitting device according to the aspect of the comparative Embodiment.

FIG. 3 is illustrating the calculation results of chromatic aberration based on the light-emitting device according to the aspect of the Embodiment of the present invention.

FIG. 4 is a schematic diagram illustrating the structure of a light-emitting device according to the aspect of the other comparative Embodiment.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ and similar terms do not necessarily denote direct and immediate connections, but also include connections through intermediate elements or devices. For purposes of convenience and clarity only, directional (up/down, etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

Various operations may be described as multiple discrete operations in turn, in a manner that may be helpful in understanding embodiments of the present invention; however, the order of description should not be construed to imply that these operations are order dependent.

It will be further understood by those of skill in the art that the apparatus and devices and the elements herein should be understood as fully operational and without limitation, and including the sub components such as operational structures, circuits, communication pathways, control switches, and related elements, any necessary elements, inputs, sensors, detectors, processors and any combinations of these structures etc. as will be understood by those of skill in the art as also being identified as or capable of operating the systems and devices and subcomponents noted herein and structures that accomplish the functions without restrictive language or label requirements since those of skill in the art are well versed in related light-emitting device fields, laser circuits, data transmission systems and operational controls and technologies of laser devices and all their sub components, including various transmission arrangements and combinations without departing from the scope and spirit of the present invention.

Referring to FIGs., the inventors set forth the Embodiments of the present invention. Referring to FIGs, the same or similar element has the same or similar sign. However, it must be paid attention that FIGs are schematic. In addition, hereinafter, the aspect of the Embodiment is an example to specify the technology aspect of the present invention and the structure and the arrangement of the components are not limited to the aspect of the Embodiment. The aspect of the Embodiment of the present invention can be modified in a variety of aspects within the scope of claimed claims of the present invention.

Referring to FIG. 1, the light-emitting device according to the aspect of the Embodiment of the present invention comprises a plurality of light sources 10 and a beam-interval reducing device 30, having a first optical element 31 and a second optical element 32, to which the beam L emitted from the light source 10 is incident. A converging element 40 converges a plurality of beams L emitted from the beam-interval reducing device 30. The converged beam L is incident to the light receiving device 100.

A plurality of beams L respectively emitted from the light source 10 is incident to the first optical element 31 and a plurality of the beams L emitted from the first optical element 31 is incident to the second optical element 32. The beam-interval reducing device 30 further narrows the beam-interval of the beams incident to the first optical element 31 and emits a plurality of beams L toward the converging element 40.

The beam-interval when emitted from the second optical element 32 is reduced to be narrower than the beam-interval when incident to the first optical element 31, so that the shape of the first optical element 31 and the second optical element 32 and the arrangement thereof can be arbitrarily specified. Specifically, with regard to the first optical element 31 and the second optical element 32, the incident angle of the beam L and the emission angle thereof are adjusted so that the beam-interval D2 of the beam L emitted from the second optical element 32 is narrower than the beam-interval D1 of the beam L incident to the first optical element 31. Each shape of the first optical element 31 and the second optical element 32 is specified based on the wavelength of the beam L and so forth. In addition, each diameter of the beams L usually reduces along with the narrowing beam-interval of the beams L.

In addition, referring to FIG. 1, the light-emitting device further comprises a collimating device 20 that collimates each beam L emitted from a plurality of light sources 10 and allows the collimated beam L to be incident to the beam-interval reducing device 30. Referring to FIG. 1, the collimating device 20 comprises a collimating lens 21 prepared for each beam L emitted from the light source 10.

As set forth above, referring to FIG. 1, the light-emitting device narrows the beam-interval following collimation of each beam L emitted from a plurality of light sources 10 and combines such beams to be incident to the light receiving device 100. The light source 10 is such as a semiconductor laser and a solid laser and so forth. The light receiving device 100 is e.g., an optical fiber and the converging element 40 converges the beams L to the core element of an optical fiber. The converging element 40 is e.g., a converging lens.

The beam-interval reducing device 30 narrows the beam-interval, so that the size of a beam-bundle bundling a plurality of the beams L is reduced, and then such bundle is incident to the converging element 40. Accordingly, the light convergence of the lights obtained by combining the beams L by the converging element 40 improves and a high-brightness thereof can be achieved. Therefore, the core diameter of the optical fiber that is e.g., the light receiving device 100 can be reduced.

Now, with regard to the optical element such as a prism, the frequency of the light passing through the optical element varies, so that in some cases, a chromatic aberration takes place due to the variation of the frequency of the beam emitted from the optical element. When the chromatic aberration occurs, the traveling direction of the beam and the size thereof and so forth vary.

However, such beam-interval reducing device 30 of the optical device illustrated in FIG. 1 has the optical property, by which the first optical element 31 and the second optical element 32 cancel each chromatic aberration taking place respectively thereon when the beams L pass therethrough. Therefore, a converging element 40 converges the beams L, of which the chromatic aberration is suppressed, are emitted from the beam-interval reducing device 30 to the converging element 40.

The chromatic aberration of the beam L emitted from the beam-interval reducing device 30 is suppressed, so that each dispersion level of the beam L that respectively passes the first optical element 31 and the second optical element 32 is different from each other. Specifically, the difference between focal distances due to the wavelength of the beam L relative to the first optical element 31 and the difference therebetween relative to the second optical element 32 are different from each other. For example, the glass applied to the first optical element 31 has the lower dispersion level than the glass applied to the second optical element 32. Specifically, the refractive index of the first optical element 31 is specified lower than the refractive index of the second optical element 32, and the Abbe number of the first optical element 31 is specified larger than the Abbe number of the second optical element 32. Consequently, the second optical element 32 cancels the chromatic aberration of the beam L that occurs in the first optical element 31. For example, a prism made of crown glass is applied to the first optical element 31 and a prism made of flint glass is applied to the second optical element 32.

A combination, having an optical property by which the chromatic aberration of the beam L is canceled, of the first optical element 31 and the second optical element 32, is applied depending on the kind of the beam L. For example, when the beam L is blue light having the central wavelength in the range of approximately 440 nm to 455 nm, a prism made of crown glass having the refractive index 1.516 and the Abbe number 64.1 is applied to the first optical element 31 and a prism made of flint glass having the refractive index 1.620 and the Abbe number 36.4 is applied to the second optical element 32, adequately and respectively.

Referring to FIG. 2, with regard to the comparative example when the optical elements having the same dispersion level are applied to each of the first optical element 31 and the second optical element 32, the calculation results of the beam profiles of the beams emitted from the second optical element 32 are illustrated. Here, the beam profiles at the predetermined distance from the emission surface of the second optical element 32 are illustrated. In addition, the number in the incident angle column denotes the incident angle of the beam relative to the incident surface on the first optical element 31.

In the beam profiles referring to FIG. 2, the sign R denotes the light having 455 nm of the wavelength, the sign B denotes the light having 440 nm of the wavelength, the sign G denotes the light having 448 nm of the wavelength. Referring to FIG. 2, regardless the incident angle, the longer the distance from the emission surface of the second optical element 32 is, the more the light separates in the respectively different directions every wavelength. In other words, the chromatic aberration occurs relative to the beam emitted from the second optical element 32.

On the other hand, FIG. 3 is illustrating the calculation results of the beam profiles of the beam L emitted from the second optical element 32 when the prism made of crown glass is applied to the first optical element 31 and the prism made of flint glass is applied to the second optical element 32. Referring to FIG. 3, regardless the degree of the incident angle, the respective lights having each wavelength relative to the beams L emitted from the second optical element 32 travel in the same direction. In other words, the chromatic aberration is suppressed (removed).

As set forth above, relative to the optical device referring to FIG. 1, the chromatic aberration of the first optical element 31 and the chromatic aberration of the second optical element 32 with respect to the beams L are canceled by the beam-interval reducing device 30. Therefore, the beams L, of which the beam-interval is reduced and of which the chromatic aberration is suppressed, are incident to the converging element 40.

The optical device of a comparative example that combines the waves while narrowing the beam-interval of a plurality of beams L is illustrated in FIG. 4. Referring to FIG. 4, the optical device uses the anamorphic optical element 30A consisting of a single prism, instead of the beam-interval reducing device 30. Specifically, the beam-interval of the beams L is reduced by the anamorphic optical element 30A following collimation of the beam L emitted from the light source 10 by the collimating device 20. And the converging element 40 combines a plurality of beams L of which each beam-interval is reduced. With regards to the comparison example referring to FIG. 4, when the central wavelength of the beam L varies, a chromatic aberration occurs, so that the traveling direction of the beam and the diameter of the beam L, which passes through the anamorphic optical element 30A, vary.

In contrast, according to the optical device referring to FIG. 1, the beam-interval reducing device 30 suppresses the chromatic aberration of the beam L due to the wavelength variation of the beam L. For example, even when the central wavelength of the beam L varies due to at least one of the variation of the temperature of the periphery of the light source 10 and the variation of the driving electric current that drives the light source 10, the variation due to the chromatic aberration relative to the beam L emitted from the beam-interval reducing device 30 is suppressed. Therefore, the beam L having the predetermined traveling direction and the predetermined beam size is incident to the converging element 40, and a plurality of beams L can be combined.

Each shape and each location of the first optical element 31 and the second optical element 32 are specified arbitrarily based on the desired optical pathway of the beam L that is generated by combining the beams from the light source 10 with the converging element 40. For example, the location of the first optical element 31 and the second optical element 32, and the incident angle and the emission angle relative to the beam L are adjusted, so that the traveling direction of the beam L emitted from the second optical element 32 can be specified. In such way, the beam-interval reducing device 30 is operative as a fairing means of the beam L and a propagating pathway specifying means thereof.

As set forth above, the optical device, according to the aspect of the Embodiment set forth above, suppresses the chromatic aberration of the beams L of which beam-interval reduces. Therefore, even when the individual property of the light source 10 is different one another, or even when the temperature of the periphery of the light source 10 and the driving electric current therefor varies, the beams L of which the chromatic aberration is suppressed can be combined.

### Other Embodiments

As set forth above, the present invention is described according to the aspect of the Embodiments, but it should not be understood that any parts, description and FIGs, of the present disclosure may limit the present invention. According to the present disclosure, a person skilled in the art can realize that a variety of the alternative Embodiment and applicable technology are clear.

For example, as set for the above, the collimating device 20 that collimates the beam L emitted from the light source 10 is used, but when the collimate light is emitted from the light source 10, no collimating device 20 is mandatory.

Needless to say, the present invention may include a variety of Embodiments that are not described here. Accordingly, the scope of the technology of the present invention is specified by the invention specific matter in association with the claims of the present invention.

### REFERENCE OF SIGNS

10 Light source
20 Collimating device
21 Collimate lens
30 Beam-interval reducing device
31 First optical element
32 Second optical element
40 Converging element
100 Light receiving element

Although only a few embodiments have been disclosed in detail above, other embodiments are possible and the inventors intend these to be encompassed within this specification. The specification describes certain technological solutions- to solve the technical problems that are described expressly and inherently in this application. This disclosure describes embodiments, and the claims are intended to cover any modification or alternative or generalization of these embodiments which might be predictable to a person having ordinary skill in the art.

Also, the inventors intend that only those claims which use the words “means for” are intended to be interpreted under 35 USC 112, sixth paragraph. Moreover, no limitations from the specification are intended to be read into any claims, unless those limitations are expressly included in the claims. The description and drawings contain sufficient structures and arrangements for one of skill in the art to understand the meanings and structures intended and used herein.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure cover modifications and variations of this disclosure provided they come within the scope of the appended claims and their equivalents.

What is claimed is:

1. A light-emitting device, comprising:
a plurality of light sources;
a beam-interval reducing device;
said beam-interval reducing device further comprising:
a first optical element to which a plurality of beams emitted respectively from each said light source is incident;
a second optical element to which a plurality of beams that is emitted from said first optical element is incident;
wherein said beam-interval reducing device emits said plurality of beams while reducing a beam-interval of said plurality of beams emitted from said second optical element to be narrower than said beam-interval of said plurality of beams incident to said first optical element; and
wherein said beam-interval reducing device has an optical property by which any chromatic aberration occurring respectively of said first optical element and said second optical element are cancelled when said beams transmit through said first and said second optical elements.

2. The light-emitting device, according to claim 1, wherein:
dispersion levels of said beams that pass respectively said first optical element and said second optical element are different from each other.

3. The light-emitting device, according to claim 2, wherein:
a refractive index of said first optical element is smaller than a refractive index of said second optical element, and an Abbe number of said first optical element is larger than an Abbe number of said second optical element.

4. The light-emitting device, according to claim 3, wherein:
said first optical element is a prism made of a crown glass and said second optical element is a prism made of a flint glass.

5. The light-emitting device, according to claim 3, wherein:
a wavelength of said beam is in a range of 440 nm to 455 nm, and the refractive index of said first optical element is 1.516 and the Abbe number thereof is 64.1, and further the refractive index of said second optical element is 1.620 and the Abbe number thereof is 36.4.

6. The light-emitting device, according to claim 1, further comprising:
a converging element that converges said plurality of beams emitted from said beam-interval reducing device.

7. The light-emitting device, according claim 1, further comprising:
a collimating device that collimates respectively said plurality of beams emitted from said plurality of light sources and allows said plurality of collimated beams to be incident to said first optical element.
